(19) United States
(12) Patent Application Publication
(10) Pub. No.: US 2007/0025080 A1
(43) Pub. Date: Feb. 1, 2007

(54) Heat dissipating fan with uniform luminosity

(76) Inventors: Nien-Lwv Li, Taipei (TW); Yi-Peng Hung, Taipei (TW); Jui-Hung Cheng, Taipei (TW)

Correspondence Address: G. LINK Co., LTD, 3550 Bell Road, MINOOKA, IL, 60447, US

(21) Appl. No.: 11/193,118

(22) Filed: Aug. 1, 2005

(51) Int. Cl. H05K 7/20

(52) U.S. Cl. 361/695

(57) ABSTRACT

A heat dissipating fan with uniform luminosity includes a frame, a circuit board, a fan wheel and a luminous unit. The frame further includes an annular frame part, a substrate at the center of the annular frame part and a plurality of ribs being connected to the annular frame part and the substrate. The circuit board is attached to the substrate. The fan wheel further includes a fan hub and a plurality of translucidus fan blades circumferentially joined to the fan hub. Each of the fan blades has a plurality of light guiding granular spots intensively distributing at the top thereof to form a foggy and slightly uneven surface to generate a refraction effect with uniform light distribution such that the entire heat dissipating fan becomes well-lit to enhance effect of the integral sight appeal.

### BACKGROUND OF THE INVENTION

1. Field of the Invention

The present invention is related to a heat dissipating fan and particularly to a heat dissipating fan with uniform luminosity.

2. Brief Description of the Related Art

The conventional heat dissipating fan mostly focuses on function of heat dissipation and there is no substantial change to the appearance and subordinate functions thereof. In order to show sight appeal of the heat dissipating fan, there are heat dissipating fan with luminous function being made for this purpose.

Referring to FIGS. 1 and 2, Taiwanese Patent Official Gazette No. 53916 entitled “HEAT DISSIPATING FAN WITH LIGHTING EFFECT” includes a frame 11, a circuit board 12 disposed in the frame 11 and a fan wheel 13 rotationally attached to the circuit board 12. The frame 11 has a plurality of mounting holes 111 at the inner lateral wall thereof and each of the mounting holes 111 receives a light emitting diode 112 respectively. The fan wheel 13 is provided with a plurality of fan blades 131 at the circumference thereof. The frame 11 and the fan blades 131 are made of colorful or transparent plastic material. When the heat dissipating fan is in operation, the LED emits light to generate dynamic and vivid lighting.

Referring to FIG. 3, the light emitting diode 112 is capable of being disposed at the circuit board 12 to create the dynamic and vivid lighting as well.

However, the preceding frame 11 and fan blades 131 are made of colorful or transparent plastic material without any device related to light refraction or guidance. When the light emitting diode 112 projects light to the frame 11 or the fan blades 131, the light penetrates through directly completely instead of part of the light occurring refraction such that no effects such as light guidance and light source divergence. That is, the LED 112 provides less light projecting area and more concentrative light so that only the light source is stronger with light ness than the rest area and the integral luminance is less uniform with worse sight appeal.

### SUMMARY OF THE INVENTION

In order to solve the preceding problems, an object of the present invention is to provide a heat dissipating fan with uniform luminosity with which it is capable of obtaining a great shining area with uniform brilliance such that the entire heat dissipating fan becomes well-lit to enhance effect of the integral sight appeal.

Accordingly, a heat dissipating fan with uniform luminosity according to the present invention includes a frame, a circuit board, a fan wheel and a luminous unit.

The frame further includes an annular frame part, a substrate at the center of the annular frame part and a plurality of ribs being connected to the annular frame part and the substrate. The circuit board is attached to the substrate. The fan wheel further includes a fan hub and a plurality of translucidus fan blades circumferentially joined to the fan hub. Each of the fan blades has a plurality of light guiding granular spots intensively distributing at the top thereof to form a foggy and slightly uneven surface to generate a refraction effect with uniform light distribution such that the entire heat dissipating fan becomes well-lit to enhance effect of the integral sight appeal.

### BRIEF DESCRIPTION OF THE DRAWINGS

The detail structure, the applied principle, the function and the effectiveness of the present invention can be more fully understood with reference to the following description and accompanying drawings, in which:

FIG. 1 is a sectional view of a conventional cooling fan with a plurality of light emitting diodes attached to a frame;

FIG. 2 is a fragmentary sectional view illustrating one of the light emitting diodes being attached to the frame shown in FIG. 1;

FIG. 3 is a sectional view of a conventional cooling fan with a plurality of light emitting diodes attached to a circuit board;

FIG. 4 is an exploded perspective view of the first embodiment of a heat dissipating fan with uniform luminosity according to the present invention;

FIG. 5 is an exploded perspective view of the second embodiment of a heat dissipating fan with uniform luminosity according to the present invention;

FIG. 6 is an exploded perspective view of the third embodiment of a heat dissipating fan with uniform luminosity according to the present invention;

FIG. 7 is top view of the fourth embodiment of a heat dissipating fan with uniform luminosity according to the present invention;

FIG. 8 is top view of the fifth embodiment of a heat dissipating fan with uniform luminosity according to the present invention; and

FIG. 9 is top view of the sixth embodiment of a heat dissipating fan with uniform luminosity according to the present invention.

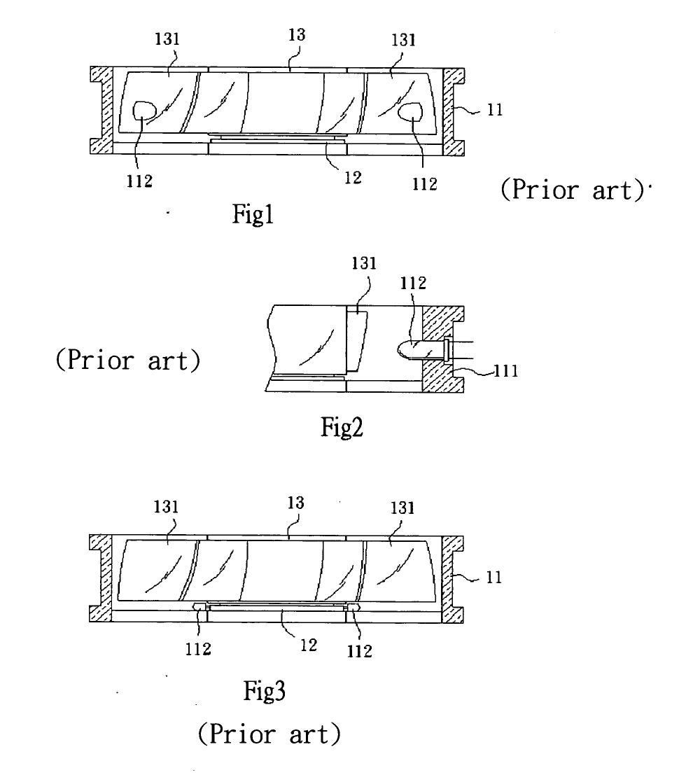

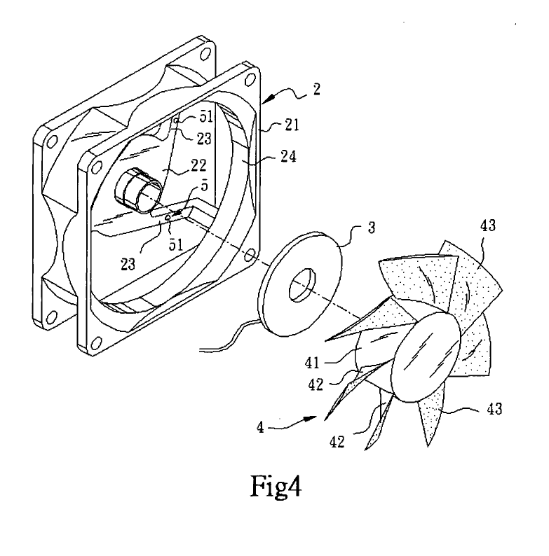

### DETAILED DESCRIPTION OF THE INVENTION

It is noted that similar parts are assigned the same reference number in the description hereinafter.

Referring to FIG. 4, the first embodiment of a heat dissipating fan with uniform luminosity according to the present invention includes a hollow frame 2, a circuit board 3, a fan wheel 4 rotationally attached to the circuit board 3 and a luminous unit 5.

The frame 2 further includes an annular frame 21, a substrate 22 at the center of the annular frame part 21 and a plurality of ribs 23 being connected to the annular frame part 21 and the substrate 22. The circuit board 3 is mounted to the substrate 22. The fan wheel 4 further includes a fan hub 41 and a plurality of translucidus fan blades 42 joined to the fan hub 41 circumferentially. Each fan blade 42 has a plurality of light guiding granular spots 43 distributing at the top thereof intensively to form a foggy and slightly uneven surface. The luminous unit 5 is composed of a plurality of light emitting diodes 51 and is disposed at the ribs 23 of the frame 2.

When the light emitting diodes 51 project light to the light guiding granular spots 43, the light guiding granular spots 43 allow the light occur phenomenon of refraction to obtain an effect of uniformly distributing the light in addition to part of the light penetrating the fan blades 42. In this way, effects of having a great shining area and illuminating evenly are capable of being reached such that the entire heat dissipating fan becomes well-lit to enhance effect of the integral sight appeal.

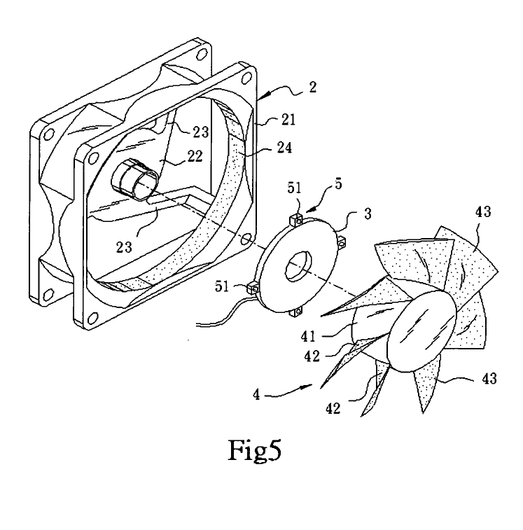

Referring to FIG. 5, the second embodiment of a heat dissipating fan with uniform luminosity according to the present invention is illustrated. The second embodiment is about the same as the first embodiment and the difference of the second embodiment is in that the light emitting diodes 51 are mounted at periphery of the circuit board 3 and the annular frame part 21 of the frame 2 is made of translucidus material. The inner side surface of the annular frame part 21 is provided with a plurality of light guiding granular spots 24 and the bottom side of the respective fan blade 42 is provided with a plurality of light guiding granular spots 43 too such that slightly uneven and foggy surfaces are formed. Similarly, the light guiding granular spots 43 allow the light occur phenomenon of refraction to obtain an effect of uniformly distributing the light in addition to part of the light penetrating the fan blades 42 and the annular frame 21 so as to obtain an effect of distributing light evenly.

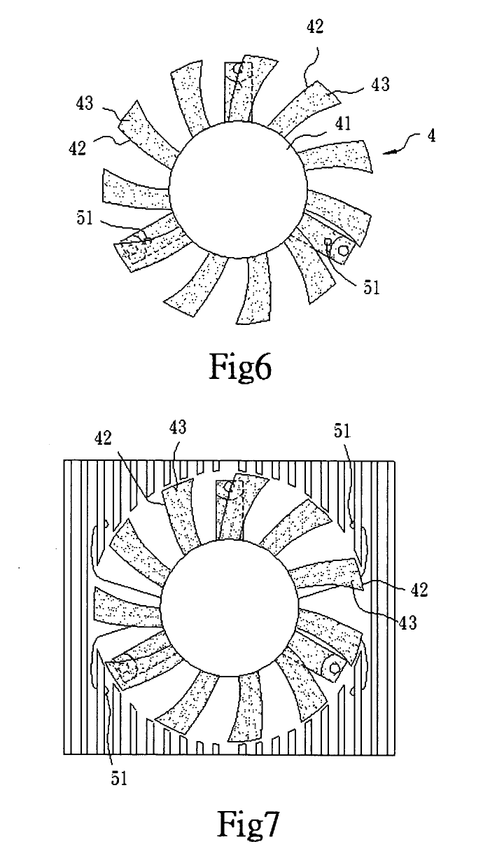

Referring to FIG. 6, the third embodiment of a heat dissipating fan with uniform luminosity according to the present invention is illustrated. The light guiding granular spots 43 are associated with fan blades 42 of an ordinary frame fan to form a slightly uneven and foggy surface on each of the fan blades 42. The light emitting diodes 51 are disposed at each of the frames and the light guiding granular spots 43 are provided at the frames too. When the light emitting diodes 51 project light toward the light guiding granular spots 43, the light guiding granular spots 43 allow the light occurring phenomenon of refraction to obtain an effect of uniformly distributing the light such that the entire frame fan becomes well-lit.

Referring to FIG. 7, the fourth embodiment of a heat dissipating fan with uniform luminosity according to the present invention is illustrated. The light guiding granular spots 43 are associated with fan blades 42 of VGA cooler to form a slightly uneven and foggy surface on each of the fan blades 42 to form a slightly uneven and foggy surface on each of the fan blades 42. When the light projects to the fan blades 42, it occurs phenomenon of refraction to obtain an effect of uniformly distributing the light.

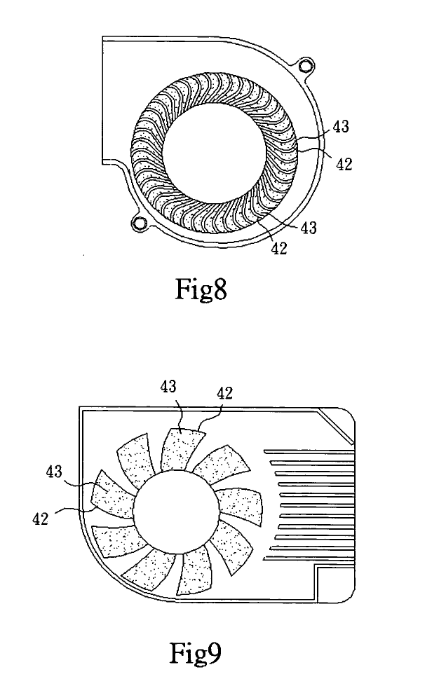

Referring to FIG. 8, the fifth embodiment of a heat dissipating fan with uniform luminosity according to the present invention is illustrated. The light guiding granular spots 43 are associated with fan blades 42 of a blower with flow passages to form a slightly uneven and foggy surface on each of the fan blades 42. When the light projects to the fan blades 42, it occurs phenomenon of refraction to obtain an effect of uniformly distributing the light.

Referring to FIG. 9, the sixth embodiment of a heat dissipating fan with uniform luminosity according to the present invention is illustrated. The light guiding granular spots 43 are associated with fan blades 42 of a radiator with a plurality of cooling fins to form a slightly uneven and foggy surface on each of the fan blades 42. The light emitting diodes 51 are provided at several ones of the cooling fins to form a foggy and slightly uneven surface on each of the fan blades 42. When the light emitting diodes 51 emit light, it occurs phenomenon of refraction to obtain an effect of uniformly distributing the light such that the entire heat dissipating fan becomes well-lit to enhance the integral sight effect as well.

As the forgoing, the heat dissipating fan with uniform luminosity according to the present invention is provided with light guiding granular spots 43 on each fan blade 42 or light guiding granular spots 24 on the annular frame part 21 to refract the light from light emitting diodes 51 mounted to the periphery of the circuit board 3 or the ribs 23 so as to create an effect of distributing light evenly. In this way, effects of having a great shining area and illuminating evenly are capable of being reached such that the entire heat dissipating fan becomes well-lit to enhance effect of the integral sight appeal.

While the invention has been described with referencing to preferred embodiments thereof, it is to be understood that modifications or variations may be easily made without departing from the spirit of this invention, which is defined by the appended claims.

What is claimed is:

1. A heat dissipating fan with uniform luminosity, comprising:
a frame, further including an annular frame part, a substrate at the center of the annular frame part and a plurality of ribs being connected to the annular frame part and the substrate;
a circuit board, being attached to the substrate;
a fan wheel, further including a fan hub and a plurality of translucidus fan blades circumferentially joined to the fan hub; and
an luminous unit;
characterized in that each of the fan blades has a plurality of light guiding granular spots distributing on the top thereof intensively to form a foggy and slightly uneven surface to generate a refraction effect with uniform light distribution.

2. The heat dissipating fan with uniform luminosity as defined in claim 1, wherein the annular frame part is made of translucidus material with the inner side surface thereof is provided with a plurality of light guiding granular spots intensively to form a foggy and slightly uneven surface.

3. The heat dissipating fan with uniform luminosity as defined in claim 1, wherein each of the fan blades has a plurality of light guiding granular spots intensively distributing at the top thereof.

4. The heat dissipating fan with uniform luminosity as defined in claim 1, wherein each of the fan blades has a plurality of light guiding granular spots intensively distributing at the bottom thereof.

5. The heat dissipating fan with uniform luminosity as defined in claim 1, wherein the luminous unit is composed of a plurality of light emitting diodes.

6. The heat dissipating fan with uniform luminosity as defined in claim 5, wherein the light emitting diodes are provided at the ribs of the frame respectively.

7. The heat dissipating fan with uniform luminosity as defined in claim 5, wherein the light emitting diodes are disposed at the periphery of the circuit board.
